(19) United States
(12) Patent Application Publication
(10) Pub. No.: US 2018/0226252 A1
(43) Pub. Date: Aug. 9, 2018

(54) Method for Planarizing Graphene Layer

(71) Applicant: TOKYO ELECTRON LIMITED, Tokyo (JP)

(72) Inventors: Ryota IFUKU, Nirasaki City (JP); Hisashi HIGUCHI, Nirasaki City (JP); Takashi MATSUMOTO, Nirasaki City (JP)

(21) Appl. No.: 15/888,445

(22) Filed: Feb. 5, 2018

(30) Foreign Application Priority Data
Feb. 6, 2017 (JP) 2017-019828

(51) Int. Cl. H01L 21/04; H01L 21/67; H01L 29/66

(52) U.S. Cl. CPC H01L 21/042; H01L 21/02527; H01L 29/66037; H01L 21/67069

(57) ABSTRACT

There is provided a method for planarizing irregularities in a surface of a grapheme layer formed on a substrate, including: planarizing the grapheme layer by removing graphene constituting a convex portion in the surface of the grapheme layer by anisotropically etching the grapheme layer using a plasma etching in an in-plane direction from an edge portion of the graphene.

### CROSS-REFERENCE TO RELATED APPLICATION

This application is based upon and claims the benefit of priority from Japanese Patent Application No. 2017-019828, filed on Feb. 6, 2017, the entire contents of which are incorporated herein by reference.

### TECHNICAL FIELD

The present disclosure relates to a method for planarizing a grapheme layer.

### BACKGROUND

Graphene is constituted as an aggregate of six-membered ring structures by a covalent bond (sp² bond) of carbon atoms. Such graphene has the unique electronic, thermal and mechanical properties derived from a six-membered ring structure composed of carbon covalent bonds, such as mobility of 200,000 cm²/Vs or more, which is 100 times or more as great as that of silicon (Si), current density of 109 A/cm², which is 1,000 times or more as great as that of Cu, thermal conductivity higher than diamond, high fracture strength, large Young's modulus, and the like.

In particular, due to such unique electronic properties, graphene is expected to be a popular new electronic device material, for example, a material for transistor channels and sensing elements.

The application of graphene to an electronic device requires a technique for forming graphene on a substrate. For example, a method of forming graphene on a substrate by plasma CVD using a hydrocarbon-based gas is known.

A single layer of graphene is a two-dimensional crystal and also has an in-plane anisotropy. The characteristics of the single layer of graphene can be controlled by controlling an edge structure of the single layer of graphene. In this connection, there has been proposed a technique for manufacturing an electronic device having desired characteristics by controlling such an edge structure by performing an anisotropic etching with respect to a graphene layer formed by CVD or the like, with hydrogen plasma generated by an inductively-coupled remote plasma system.

When a graphene layer is formed by CVD or the like, a single layer of graphene (graphene sheet) as a two-dimensional crystal or plural layers of graphene is obtained. In this case, an atomic level of irregularities, namely variation in the layer number of graphene sheets, may often occur. In the case of manufacturing an electronic device with graphene, the atomic level of irregularities caused by the variation in the layer number of graphene sheets may vary physical properties and processing characteristics of the graphene itself. This varies device characteristics, for example, a transistor threshold value, which may result in a poor yield. For this reason, in the application of graphene to an electronic device, a planarization technique for eliminating such atomic-level irregularities in the graphene layer is extremely important.

CMP is being widely used as a planarization technique in semiconductor processes. However, since CMP is a technique based on a mechanical polishing, it is difficult to achieve planarization at an atomic level. Applications of CMP to planarization of a graphene layer have never been reported.

Meanwhile, although not intended for planarization, there has been proposed a technique for removing atomic layers one by one from a surface of graphene by reacting a reactive substance with the graphene under irradiation of ultraviolet rays.

Such a conventional technique is to control the layer number of graphene by removing the atomic layers one by one. However, even when this technique is applied to the planarization in the case where an atomic-level of irregularities exists, since the atomic layers are removed one by one as a whole, irregularities due to variation in the number of graphene layers cannot be eliminated in principle, which makes it difficult to achieve the planarization of the graphene layer.

### SUMMARY

Some embodiments of the present disclosure provide a technique capable of planarizing a surface of a graphene layer formed on a substrate by eliminating irregularities in the surface of the graphene layer.

According to one embodiment of the present disclosure, there is provided a method for planarizing irregularities in a surface of a grapheme layer formed on a substrate, including: planarizing the grapheme layer by removing graphene constituting a convex portion in the surface of the grapheme layer by anisotropically etching the grapheme layer using a plasma etching in an in-plane direction from an edge portion of the graphene.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIGS. 1A to 1C are cross-sectional process view schematically showing a graphene layer planarizing method according to an embodiment of the present disclosure.

FIG. 2 is a cross-sectional process view showing a microwave plasma processing apparatus which is an example of an apparatus suitable for the graphene layer planarizing method according to the embodiment.

FIG. 3 is a view showing topographic images obtained by AFM and the height of a portion thereof in an experimental example in which a graphene layer is etched by hydrogen plasma generated using the microwave plasma processing apparatus of FIG. 2, while changing a period of time.

FIG. 4 is a view showing the relationship between an etching time and an etching length in an experimental example in which graphene is etched by the hydrogen plasma generated using the microwave plasma processing apparatus of FIG. 2, while changing a period of time.

FIG. 5 is a view showing the relationship between an etching time and an etching rate in an experimental example in which graphene is etched by the hydrogen plasma generated using the microwave plasma processing apparatus of FIG. 2, while changing a period of time.

FIG. 6 is a view showing images obtained by binarizing AFM images with the etching time in FIG. 3 changed and a convex ratio (convex area/total area) thereof.

FIG. 7 is a graph showing the relationship between the etching time and the convex ratio based on the result of FIG. 6.

### DETAILED DESCRIPTION

Hereinafter, embodiments of the present disclosure will be described in detail with reference to the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### <Generation of Graphene Layer>

First, the generation of a graphene layer, which is a base for the planarization of a graphene layer, will be described in brief.

As described earlier, graphene has a two-dimensional crystal. In a case where such a graphene is applied to an electronic device, a single layer of graphene (graphene sheet) or plural layers of graphene is generated on a substrate. At this time, the generation of the graphene layer can be performed by, for example, a plasma CVD using a hydrocarbon-based gas. At this time, the substrate is not particularly limited but may be a metal, a semiconductor or an insulator. Alternatively, the substrate may be either crystalline or amorphous. For example, a substrate in which an SiO₂ film is formed on a semiconductor Si may be suitably used.

When a graphene layer is formed on a substrate by the plasma CVD or the like, even if the graphene layer has a macroscopically uniform thickness, an atomic-level of irregularities, namely a variation in the layer number of graphene sheets, may be often formed in the surface of the graphene layer.

In the case of manufacturing an electronic device with graphene, a technique for controlling a structure of an end portion of the graphene by performing, for example, the hydrogen plasma-based anisotropic etching as described in the Background section of the present disclosure with respect to the graphene layer formed in the aforementioned manner, may be used. However, in such a case of manufacturing an electronic device, the atomic-level of irregularities which is caused by the variation in the layer number of graphene sheets, may cause variations in physical properties and processing characteristics of the graphene itself. This varies device characteristics, for example, a threshold value of a transistor, which may result in a poor yield. For this reason, in order to eliminate the atomic-level of irregularities caused by the variation in the layer number of graphene sheets, the graphene is planarized, as will be described hereinafter.

### <Method for Planarizing Graphene Layer>

Next, a graphene layer planarizing method according to an embodiment of the present disclosure will be described.

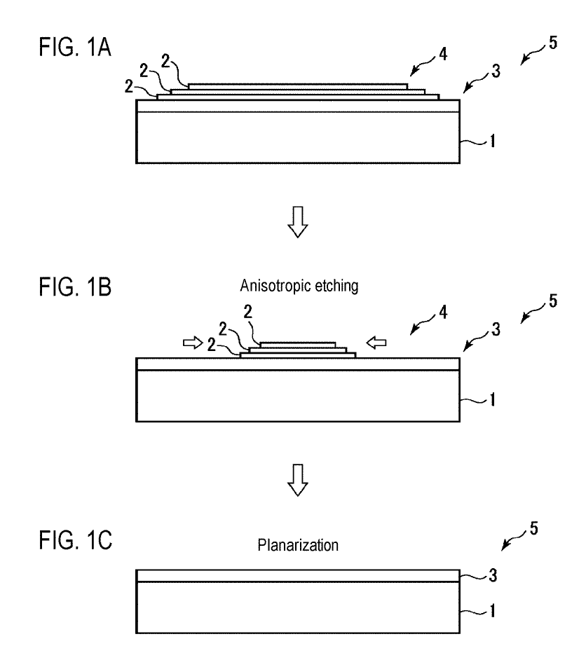

FIGS. 1A to 1C are cross-sectional process views schematically showing the graphene layer planarizing method according to an embodiment of the present disclosure.

FIG. 1A shows a workpiece 5 with a graphene layer 3 formed thereon, the graphene layer 3 being obtained by forming a single layer or plural layers of graphene sheet 2 as a two-dimensional crystal on the substrate 1 by, for example, a plasma CVD using a hydrocarbon gas. FIG. 1A also shows variations in the layer number of graphene sheets 2. In FIG. 1A, a convex portion 4 is schematically shown as being formed on the surface of the graphene layer 3 due to variations in the layer number of graphene sheets 2, but in practice, the graphene sheet 2 is an atomic layer and the surface of the graphene layer 3 has many microscopic atomic-level irregularities due to the variations in the layer number of graphene sheets 2.

As described above, when the variations in the layer number of graphene sheets 2 is present in the graphene layer 3, the graphene sheets 2 constituting the convex portion 4 necessarily have edge portions.

In view of the foregoing, in the present embodiment, as shown in FIG. 1B, a plasma etching is used to remove the graphene sheets 2 constituting the convex portion 4 formed on the surface of the graphene layer 3 by allowing the graphene sheets 2 to be subjected an anisotropic etching with high directionality in an in-plane direction from the edge portions of the graphene sheets 2. That is to say, since graphene is a two-dimensional crystal, the etching proceeds substantially only in the in-plane direction so that the etching proceeds at an extremely high aspect ratio (2,000 or more). Therefore, only graphene sheets constituting the convex portions due to the variations in the layer number are etched, and the graphene sheets continuously extending downward from the etched graphene sheets remain unetched so that a flat surface is formed at the atomic layer level.

As such etching proceeds, as shown in FIG. 1C, all of the convex portions 4 are finally removed so that the surface of the graphene layer 3 is planarized without an atomic-level of irregularities.

The plasma etching used at this time is not particularly limited as long as the anisotropic etching can be performed in the in-plane direction. As an example, a hydrogen plasma may be used. By using hydrogen plasma, etching is mainly performed by hydrogen radicals in the hydrogen plasma. It is therefore possible to substantially suppress damage to graphene sheets continuously extending downward from the graphene sheets that constitute the irregularities.

A method for the plasma etching is also not particularly limited. As an example, the inductively-coupled remote plasma as described in the Background section of the present disclosure may be used. However, it is preferable to use microwave plasma from the viewpoint of increasing an etching rate to efficiently perform the planarization. Microwave plasma is plasma with low electron temperature and high density, and substantially increases the radical density. Thus, it is contemplated that the etching can be performed by the microwave plasma at a high etching rate. For example, in the case of the hydrogen plasma etching based on inductively-coupled plasma, the etching rate is about 6 nm/min at the maximum as described in the Background section of the present disclosure, whereas, in the case of the hydrogen plasma etching based on the microwave plasma, the etching rate is 50 nm/min or more, which can be further increased by appropriately selecting apparatus configurations and conditions.

In addition, since the microwave plasma has a low electron temperature, plasma processing with less damage can be performed.

An apparatus for generating the microwave plasma is also not particularly limited. As an example, an apparatus configured to radiate a microwave propagating through a waveguide from slots formed in a planar slot antenna may be used. Therefore, it is possible to further increase the etching rate by appropriately selecting manufacturing conditions.

The hydrogen plasma-based anisotropic etching is described in the Background section of the present disclosure. Hydrogen plasma-based anisotropic etching is used to form an electronic device having predetermined characteristics by etching a specific crystal plane of graphene and controlling an edge structure of the graphene. This type of anisotropic etching substantially differs from the present disclosure in that the surface of the graphene layer is planarized at the atomic-level before forming the electronic device as in the present disclosure. The term “anisotropic etching” described in the Background section of the present disclosure means etching a specific crystal plane in the in-plane direction of graphene, whereas the term “anisotropic etching” described in the present disclosure means that it has selectivity in the in-plane direction.

### Example of Apparatus Suitable for Anisotropic Etching for Planarization

Next, an example of an apparatus suitable for anisotropic etching for planarizing a graphene surface will be described.

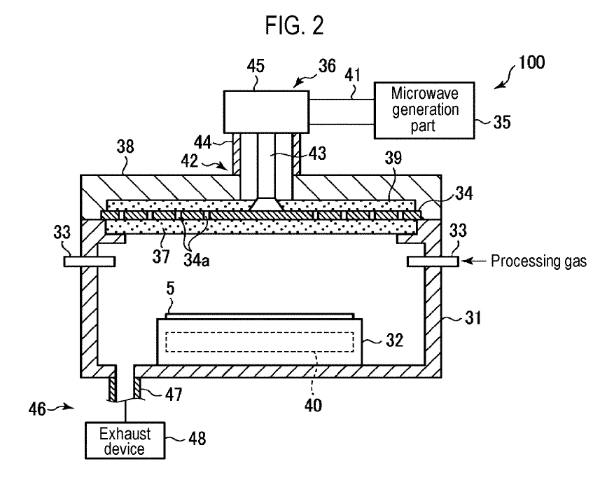

FIG. 2 is a cross-sectional view showing a microwave plasma processing apparatus which is an example of an apparatus suitable for anisotropic etching of graphene. The microwave plasma processing apparatus 100 includes a cylindrical processing container 31, a mounting table 32 disposed inside the processing container 32 and on which a workpiece is mounted, a gas introduction port 33 formed in the side wall of the processing container 31 to introduce a processing gas therethrough, a planar slot antenna 34 disposed so as to face an opening defined at the top of the processing container 31 and has a plurality of slots 34a formed to transmit a microwave therethrough, a microwave generation part 35 which generates a microwave, a microwave transmission mechanism 36 which guides the microwave generated from the wave generation part 35 to the planar slot antenna 34, a microwave-transmitting plate 37 disposed on the lower surface of the planar slot antenna 34 and is made of a dielectric material, and an exhaust part 46.

A shield member 38 having a water cooling structure is disposed on the planar slot antenna 34. A slow-wave member 39 made of a dielectric material is disposed between the shield member 38 and the planar slot antenna 34.

The planar slot antenna 34 is composed of, for example, a copper plate or an aluminum plate whose surface is plated with silver or gold, and has the plurality of slots 34a for radiating microwaves therethrough, formed with a predetermined pattern so as to penetrate through the plate. The pattern of the slots 34a is appropriately set so that the microwaves are uniformly radiated. An example of the appropriate pattern is a radial line slot in which a plurality of pairs of slots 34a is concentrically arranged, with each pair composed of two slots 34a paired in a T-shape. The length of each slot 34a and the arrangement interval between the slots 34a are appropriately determined depending on the effective wavelength (λg) of a microwave. The slot 34a may have any other shape such as a circular shape, an arc shape, or the like. The arrangement shape of the slots 32 is not particularly limited. For example, the slots 34a may be arranged spirally or radially other than concentrically. The pattern of the slots 34a is appropriately set so as to provide the microwave radiation characteristics by which a desired plasma density distribution is obtained.

The slow-wave member 39 is disposed on the upper surface of the planar slot antenna 34. The slow-wave member 39 is made of a dielectric material having a larger dielectric constant than a vacuum, for example, quartz, ceramics (Al₂O₃), resin such as polytetrafluoroethylene or polyimide or the like. The slow-wave member 39 has a function of making the wavelength of the microwave shorter than that in a vacuum, thereby making the planar slot antenna 34 smaller.

The thicknesses of the microwave-transmitting plate 37 and the slow-wave member 39 are adjusted so that an equivalent circuit established by the slow-wave member 39, the planar slot antenna 34, the microwave-transmitting plate 37 and plasma meets resonance conditions. By adjusting the thickness of the slow-wave member 39, the phase of the microwave can be adjusted. Further, by adjusting the thickness of the slow-wave member 39 so that the connection portion with the planar slot antenna 34 becomes an “antinode” of a standing wave. Thus, the reflection of the microwave is minimized and the radiant energy of the microwave is maximized. In addition, the reflection of the microwave in the interface can be prevented when the slow-wave member 39 and the microwave-transmitting plate 37 are made of the same material.

The gas introduction port 33 is to introduce a plasma generation gas and an etching gas into the processing container 31 therethrough. In this embodiment, a H₂ gas is used as the etching gas. A gas supply pipe (not shown) is connected to the gas introduction port 33. A gas supply source (not shown) for supplying the plasma generation gas and the H₂ gas is connected to the gas supply pipe. These gases are supplied from the gas supply source into the gas introduction port 33 via the gas supply pipe and are introduced from the gas introduction port 33 into the processing container 31. As the plasma generation gas, a noble gas such as Ar, Kr, Xe, He or the like is used. Among these, the Ar gas may be used. The use of the plasma generation gas is not essential and only the H₂ gas may be used.

The microwave transmission mechanism 36 includes a waveguide 41 for guiding the microwave therethrough and extending in the horizontal direction from the microwave generation part 35, a coaxial waveguide 42 extending upward from the planar slot antenna 34 and including an inner conductor 43 and an outer conductor 44, and a mode conversion mechanism 45 installed between the waveguide 41 and the coaxial waveguide 42. The microwave generated by the microwave generation part 35 propagates through the waveguide 41 in a TE mode. The oscillation mode of the microwave is converted from the TE mode to a TEM mode in the mode conversion mechanism 45. The microwave converted to the TEM mode is guided to the slow-wave member 39 through the coaxial waveguide 42 and subsequently is radiated from the slow-wave member 39 into the processing container 31 through the slots 34a of the planar slot antenna 34 and the microwave-transmitting plate 37. The frequency of the microwave may fall within a range of 300 MHz to 10 GHz. For example, the frequency of the microwave may be 2.45 GHz.

The exhaust part 46 includes an exhaust pipe 47 connected to the bottom of the processing container 31, and an exhaust device 48 equipped with a vacuum pump and a pressure control valve. The interior of the processing container 31 is exhausted by the vacuum pump of the exhaust device 48 through the exhaust pipe 47. The pressure control valve is installed in the exhaust pipe 47. An internal pressure of the processing container 31 is controlled by the pressure control valve.

The mounting table 32 is provided with a temperature control mechanism 40 so that a temperature of the workpiece 5 mounted on the mounting table 32 can be controlled to a predetermined temperature ranging from room temperature to 800 degrees C., for example.

Located in the side wall of the processing container 31 is a loading/unloading port (not shown) for transferring the workpiece 5 between the processing container 31 and a transfer chamber installed adjacent to the processing container 31. The loading/unloading port is opened and closed by a gate valve (not shown).

### <Planarizing Method Performed by Microwave Plasma Processing Apparatus>

The anisotropic etching for planarizing the surface of the graphene layer with the microwave plasma processing apparatus 100 configured as above is performed as follows. First, the workpiece 5 having a graphene layer is loaded into the processing container 31 and is mounted on the mounting table 32. The internal pressure of the processing container 31 is controlled to have a predetermined value and the workpiece 5 is heated to a predetermined temperature under the control of the temperature control mechanism. At this time, the workpiece 5 is subjected to a surface treatment using an H₂ gas. In addition to the H₂ gas, a noble gas such as an Ar gas or the like may be used. This treatment is to remove particles or dust adhering to the surface of the workpiece 5 and to clean the surface. The surface treatment is not essential.

An example of conditions for the surface treatment may be as follows:
Flow rate of Gas: Ar/H₂=0 to 2,000/10 to 2,000 sccm
Pressure: 0.1 to 10 Torr (13.3 to 1,333 Pa)
Temperature of Workpiece: 300 to 600 degrees C.
Time period: 10 to 120 min

Subsequently, in a state where the interior of the processing container 31 is maintained at the same pressure as above, and the temperature of the workpiece 5 is adjusted to a predetermined temperature, the H₂ gas alone or both the H₂ gas and the noble gas such as an Ar gas, which is a plasma generation gas, is (are) introduced into the processing container 31 to generate a microwave plasma. In this manner, the anisotropic etching for planarizing the graphene layer is performed.

In generating the microwave plasma, the microwave generated by the microwave generation part 35 is guided to the slow-wave member 39 through the waveguide 41, the mode conversion mechanism 45 and the coaxial waveguide 42 of the microwave transmission mechanism 36, and is radiated into the processing container 31 through a series of slow-wave members 39, the slots 34a of the planar slot antenna 34 and the microwave-transmitting plate 37.

The microwave spreads as a surface wave into a region immediately under the microwave-transmitting plate 37 to generate surface wave plasma. Then, the surface wave plasma spreads downward, thereby becoming plasma having a high hydrogen radical density and a low electron temperature in a region at which the workpiece 5 is disposed.

By using such microwave plasma, it is possible to anisotropically etch graphene sheets constituting irregularities on the surface of the graphene layer of the workpiece 5 at a high etching rate, starting from edge portions of the graphene sheets. It is therefore possible to planarize the surface of the graphene layer at an atomic level.

The conditions for the hydrogen plasma process based on the microwave plasma may be as follows:
Flow rate of Gas: Ar/H₂=0 to 2,000/10 to 2,000 sccm
Pressure: 0.1 to 10 Torr (13.3 to 1,333 Pa)
Temperature of workpiece: room temperature to 800 degrees C.
Microwave power: 0.5 to 5 kW

At this time, the etching rate of graphene greatly varies depending on the temperature. Thus, the temperature may be 400 degrees C. or more, specifically 450 degrees C. or more. The etching rate is at an extremely high level of 80 nm/min at 400 degrees C. and 290 nm/min at 470 degrees C.

As described above, according to the present embodiment, the atomic-level of irregularities caused by the variation in the layer number of graphene sheets in the graphene layer can be anisotropically etched by the plasma etching only in the in-plane direction, starting from the edge portions of the graphene sheets constituting the irregularities. It is therefore possible to eliminate the atomic-level of irregularities, thereby planarizing the surface of the graphene layer at an atomic level. Thus, in the case where graphene is used for an electronic device, it is possible to substantially suppress variations in device characteristics, for example, a transistor threshold value.

### Experimental Example

Next, an experiment example will be described.

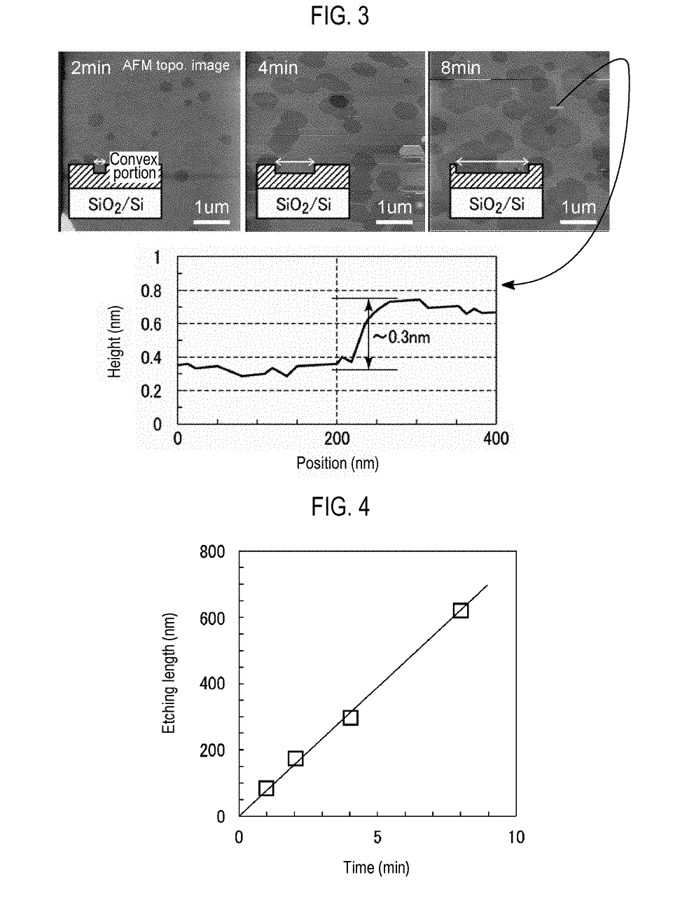

Here, for a sample in which a graphene layer is formed on an SiO₂/Si substrate, the etching was performed with the hydrogen plasma while changing a period of time, using the microwave plasma processing apparatus 100 shown in FIG. 2, under the conditions that the flow rate of the Ar gas is 500 sccm, the flow rate of the H₂ gas is 500 sccm, the pressure is 3 Torr, the temperature is 400 degrees C., and the microwave power is 1 kW. FIG. 3 is a view showing topographic images taken by an atomic force microscope (AFM) and the height of a portion thereof when the period of time is changed as 2 min, 4 min and 8 min. In the topographic images, a darker color indicates a lower height. It was confirmed from this figure that a convex portion of the outermost layer was etched starting from the respective edge portion, and a regular hexagonal etched portion (planarized portion) having a depth of 0.3 nm, which corresponds to the thickness of the single layer of graphene, was formed. It can be also seen from this figure that the planarized portion spreads with time.

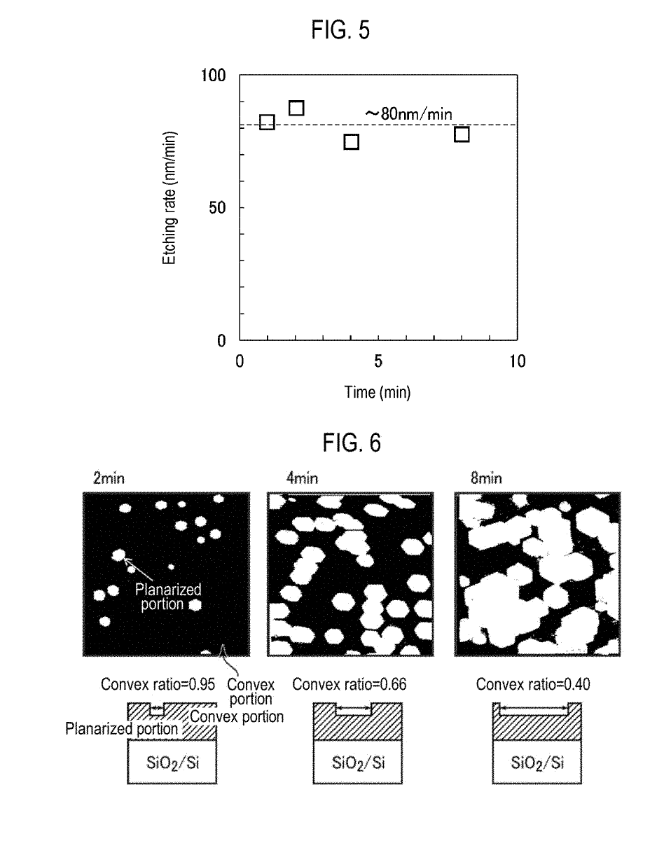

FIG. 4 shows an etching length at each etching time (a length from the center of the regular hexagon portion as the etched portion to the midpoint of one side). It was confirmed from this figure that the etching length was increased with time to almost 600 nm at 8 min, and the single layer of graphene with the thickness of 0.3 nm of the graphene sheet was anisotropically etched. The aspect ratio at this time was 600 nm/0.3 nm=2,000 and the etching rate at each etching time was approximately 80 nm/min as shown in FIG. 5.

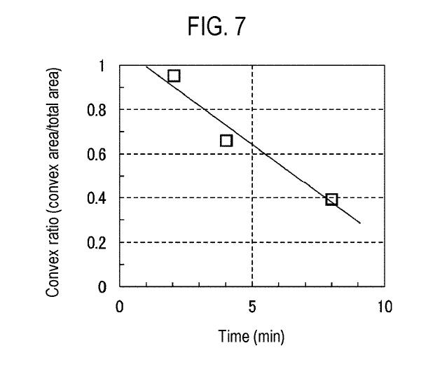

Next, the AFM images were binarized focusing on the convex portion of the outermost layer and the planarized portion of the underlying layer. FIG. 6 shows images obtained by binarizing the AFM images of FIG. 3, in which white portions indicate the planarized portions and black portions indicate the convex portions. A “convex ratio” (=convex area/total area) obtained by dividing the convex area by the total area was 0.95 at an etching time of 2 min, 0.66 at an etching time of 4 min and 0.40 at an etching time of 8 min FIG. 7 is a graph showing the relationship between the etching time and the convex ratio based on the results of FIG. 6. It can be seen from this graph that the convex ratio decreases linearly with the increase in etching time. From this result, when a straight line is extrapolated, it is expected that all convex portions are etched at an etching time of about 12.5 min and the surface of the graphene layer is planarized.

### OTHER APPLICATIONS

Although the embodiments of the present disclosure have been described above, the present disclosure is not limited to the above-described embodiments but various modifications can be made without departing from the spirit and scope of the present disclosure. For example, although the example in which the etching for planarization is performed by the microwave plasma processing apparatus using the planar slot antenna has been described in the above embodiments, the present disclosure is not limited thereto but the etching for planarization may performed by other microwave plasma processing apparatuses as long as the graphene can be anisotropically etched in the in-plane direction.

Further, a substrate on which the graphene to be etched is formed is not particularly limited as described above but an appropriate substrate may be used depending on the intended use.

According to the present disclosure in some embodiments, graphene constituting convex portions in a surface of a graphene layer is removed by being anisotropically etched using a plasma etching in the in-plane direction from respective edge portions. It is therefore possible to remove irregularities formed on the surface of the graphene layer, thereby planarizing the surface of the graphene layer at an atomic level.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method for planarizing irregularities in a surface of a grapheme layer formed on a substrate, comprising:
planarizing the grapheme layer by removing graphene constituting a convex portion in the surface of the grapheme layer by anisotropically etching the grapheme layer using a plasma etching in an in-plane direction from an edge portion of the graphene.

2. The method of claim 1, wherein the plasma etching is a hydrogen plasma-based etching.

3. The method of claim 1, wherein the plasma etching is performed with a microwave plasma.

4. The method of claim 3, further comprising: in a state where a workpiece having the graphene layer formed on the substrate is accommodated in a processing container, supplying a processing gas into the processing container and radiating a microwave into the processing container to generate the microwave plasma inside the processing container.

5. The method of claim 4, wherein the microwave is guided from a microwave generation part to a planar slot antenna and subsequently is radiated from a predetermined pattern of slots formed in the planar slot antenna into the processing container.

6. The method of claim 5, wherein an antenna having radial line slots formed therein is used as the planar slot antenna.

7. The method of claim 4, wherein, in a case where the plasma etching is the hydrogen plasma-based etching, the processing gas contains a hydrogen gas alone, or both the hydrogen gas and a noble gas.

8. The method of claim 1, further comprising: before the planarizing the graphene layer with the plasma etching, performing a surface treatment on the graphene by a processing gas including a hydrogen gas.

9. The method of claim 8, wherein a temperature during the surface treatment falls within a range of 300 to 600 degrees C.
